(19) United States
(12) Patent Application Publication
(10) Pub. No.: US 2026/0122770 A1
(43) Pub. Date: Apr. 30, 2026

(54) WEARABLE DEVICE INCLUDING CONDUCTIVE MEMBER FORMING INDUCTION PATH FOR ELECTROSTATIC DISCHARGE

(71) Applicant: Samsung Electronics Co., Ltd., Suwon-si (KR)

(72) Inventors: Yongjun CHOI, Suwon-si (KR); Jongchul HONG, Suwon-si (KR)

(21) Appl. No.: 19/432,556

(22) Filed: Dec. 24, 2025

Related U.S. Application Data
(63) Continuation of application No. PCT/KR2024/006828, filed on May 21, 2024.

(30) Foreign Application Priority Data
Jul. 20, 2023 (KR) 10-2023-0094933
Jul. 17, 2023 (KR) 10-2023-0092318

(51) Int. Cl. H05K 1/02; G04G 17/04; H02H 9/00; H02H 9/04

(52) U.S. Cl. CPC H05K 1/0259; G04G 17/04; H02H 9/005; H02H 9/04

(57) ABSTRACT

A wearable device is provided. The wearable device includes a housing including a metal cover, a printed circuit board in the housing, a protection circuit disposed on the printed circuit board, and a conductive member disposed between the printed circuit board and the metal cover. The protection circuit is electrically connected to a ground of the printed circuit board. The conductive member is electrically connected to the protection circuit to form an electrostatic discharge induction path.

### CROSS-REFERENCE TO RELATED APPLICATIONS

This application is a continuation application, claiming priority under 35 U.S.C. § 365(c), of an International application No. PCT/KR2024/006828, filed on May 21, 2024, which is based on and claims the benefit of a Korean patent application number 10-2023-0092318, filed on July 17, 2023, in the Korean Intellectual Property Office, and of a Korean patent application number 10-2023-0094933, filed on July 20, 2023, in the Korean Intellectual Property Office, the disclosure of each of which is incorporated by reference herein in its entirety.

### BACKGROUND

### 1. Field

The disclosure relates to a wearable device that includes a conductive member forming an electrostatic discharge induction path.

### 2. Description of Related Art

Various portable communication devices such as smart phones, tablets, and wearable devices are being developed. Among them, wearable devices such as smart watches are gaining significant popularity due to the various functions and convenience they offer.

Meanwhile, electrostatic discharge (ESD) is a phenomenon in which an instantaneous current flows between two objects with different electric potentials due to the accumulation of static charge. For example, when an object with accumulated static charge contacts a conductor, static electricity may suddenly discharge, thereby generating an instantaneous current flow between the two objects.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a wearable device that includes a conductive member forming an electrostatic discharge induction path.

Additional aspects will be set forth in part in the description which follows and, in part, will be apparent from the description, or may be learned by practice of the presented embodiments.

In accordance with an aspect of the disclosure, a wearable device is provided. The wearable device includes a housing including a metal cover, a printed circuit board (PCB) within the housing, a protection circuit disposed on the PCB, and a conductive member disposed between the PCB and the metal cover, wherein the protection circuit is electrically connected to a ground of the PCB, and wherein the conductive member is electrically connected to the protection circuit to form an electrostatic discharge induction path.

In accordance with another aspect of the disclosure, a wearable device is provided. The wearable device includes a housing including a first cover including a conductive portion, a printed circuit board (PCB) within the housing, a protection circuit on the PCB, a sensor within the housing configured to detect biometric information of a user using the conductive portion of the first cover, and a conductive member disposed between the PCB and the first cover to overlap the conductive portion, wherein the protection circuit is electrically connected to a ground of the PCB, and wherein the conductive member is electrically connected to the protection circuit to form a path for electrostatic discharge by the conductive portion.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a front perspective view of an electronic device according to an embodiment of the disclosure;

FIG. 2 is a rear perspective view of an electronic device according to an embodiment of the disclosure;

FIG. 3 is an exploded perspective view of an electronic device according to an embodiment of the disclosure;

FIG. 4 is a cross-sectional view of an electronic device according to an embodiment of the disclosure;

FIG. 5 is an exploded view illustrating a partial configuration of an electronic device according to an embodiment of the disclosure;

FIG. 6 is an exploded view illustrating a partial configuration of an electronic device according to an embodiment of the disclosure;

FIG. 7 is an exploded view illustrating a partial configuration of an electronic device according to an embodiment of the disclosure;

FIG. 8 is a drawing illustrating both surfaces of a conductive member according to an embodiment of the disclosure;

FIG. 9 is a drawing illustrating an ESD prevention effect by a conductive member according to an embodiment of the disclosure;

FIG. 10 is a drawing illustrating shapes of a conductive member according to an embodiment of the disclosure;

FIG. 11 is a cross-sectional view of an electronic device according to an embodiment of the disclosure; and

FIG. 12 is a block diagram of an electronic device in a network environment according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

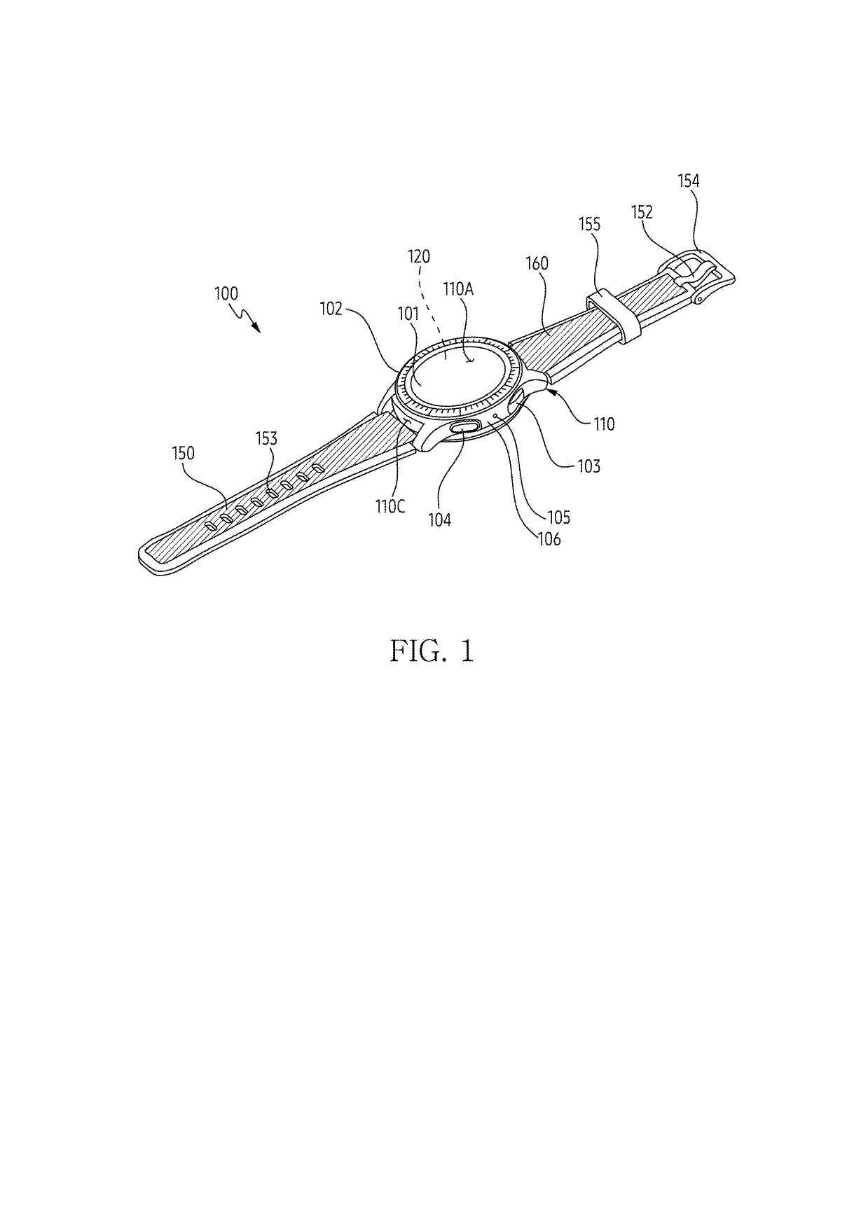

FIG. 1 is a front perspective view of an electronic device 100 according to an embodiment of the disclosure.

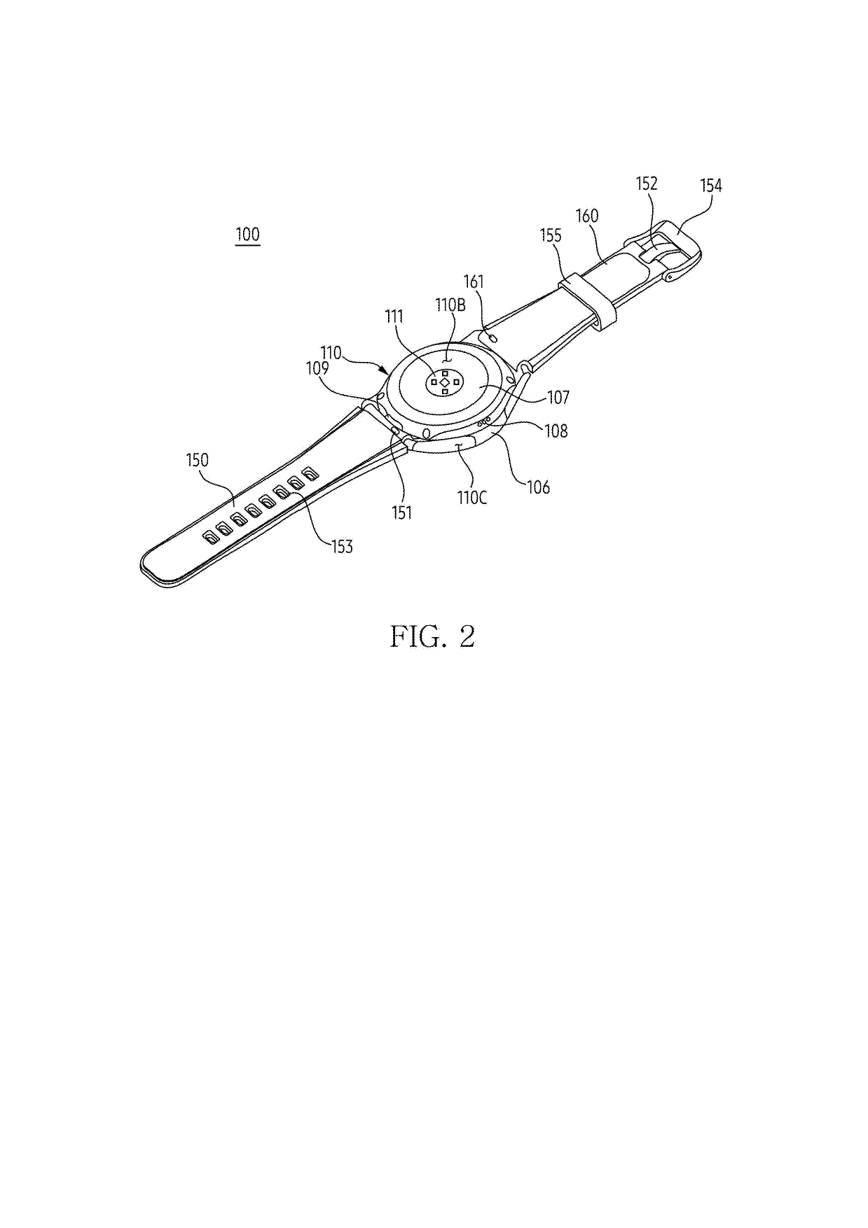

FIG. 2 is a rear perspective view of the electronic device 100 according to an embodiment of the disclosure.

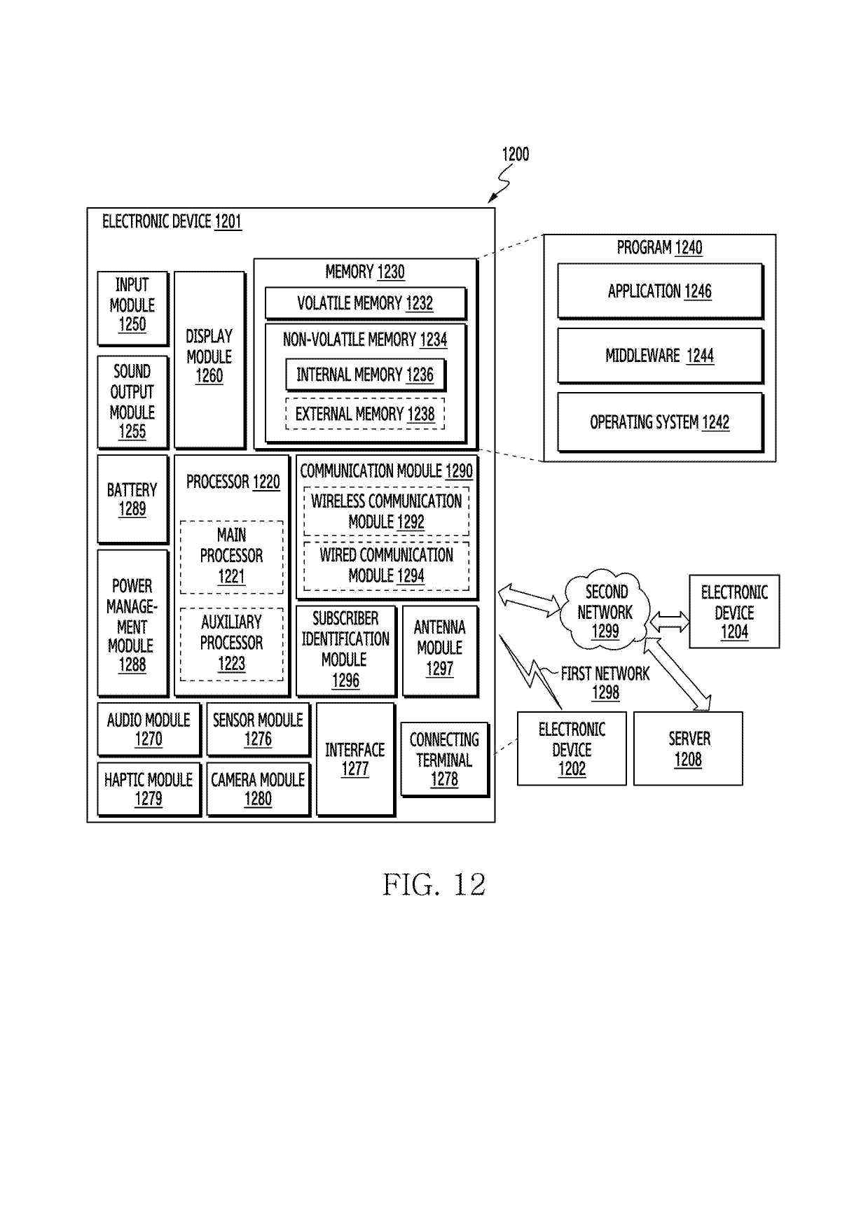

Referring to FIGS. 1 and 2, the electronic device 100 (e.g., an electronic device 1201 of FIG. 12) according to an embodiment may include a housing 110 that forms a front surface 110A, a rear surface 110B, and a side surface 110C surrounding a space between the front surface 110A and the rear surface 110B, and fastening members 150 and 160 that are connected to at least a portion of the housing 110 and configured to detachably fasten the electronic device 100 to a part of a body (e.g., a wrist and the like) of a user. For example, the electronic device 100 may be referred to as a wearable electronic device.

The housing 110 may refer to a structure that forms at least a portion of the front surface 110A, the rear surface 110B, and the side surface 110C. In an embodiment, the front surface 110A may be formed by a front plate 101 (e.g., a glass plate or a polymer plate including various coating layers) in which at least a portion is formed to be substantially transparent. The rear surface 110B may be formed by a substantially opaque rear plate 107. The rear plate 107 may be formed by, for example, coated or tinted glass, ceramic, polymer, metal (e.g., aluminum, stainless steel (STS), or magnesium), or a combination of at least two of the materials. The side surface 110C may be formed by a frame 106 coupled to the front plate 101 and the rear plate 107. For example, the frame 106 may include metal. For example, the frame 106 may be referred to as a "metal frame", "side member", or "side bezel structure".

The fastening members 150 and 160 may be formed in various materials and shapes. For example, the fastening members 150 and 160 may be formed as an integral type or as a plurality of unit links that are movable relative to each other, by using woven fabric, leather, rubber, urethane, metal, ceramic, or a combination of at least two of the materials.

According to an embodiment, the electronic device 100 may include at least one of a display 120, an audio module (e.g., a sound output module 1255 and/or an audio module 1270 of FIG. 12), a sensor module 111, key input devices 102, 103, and 104, and a connector hole 109. In some embodiments, the electronic device 100 may omit at least one of the components (e.g., the key input devices 102, 103, and 104, the connector hole 109, or the sensor module 111) or may additionally include another component.

The display 120 may be exposed, for example, through a substantial portion of the front plate 101. A shape of the display 120 may be a shape corresponding to a shape of the front plate 101 and may take various forms such as circular, elliptical, or polygonal. The display 120 may be coupled to or disposed adjacent to touch sensing circuitry, a pressure sensor capable of measuring intensity (pressure) of a touch, and/or a fingerprint sensor.

The audio module may include a microphone hole 105 and a speaker hole 108. A microphone for obtaining external sound may be disposed inside the microphone hole 105. The microphone may include a plurality of microphones to detect a direction of sound, but is not limited thereto. The speaker hole 108 may be used as an external speaker and a receiver for calls. In some embodiments, the speaker hole 108 may be integrated with the microphone hole 105 such that the speaker hole 108 and the microphone hole 105 are implemented as one hole, or a speaker may be included without the speaker hole 108 (e.g., a piezo speaker).

The sensor module 111 may generate an electrical signal or a data value corresponding to an internal operating state of the electronic device 100 or an external environmental state. The sensor module 111 may include, for example, the sensor module 111 (e.g., a heart rate monitor (HRM) sensor) disposed on the rear surface 110B of the housing 110. The electronic device 100 may further include at least one sensor module not illustrated, for example, a gesture sensor, a gyro sensor, a barometric pressure sensor, a magnetic sensor, an acceleration sensor, a grip sensor, a color sensor, an infrared (IR) sensor, a biosensor, a temperature sensor, a humidity sensor, or an illuminance sensor.

In an embodiment, the key input devices 102, 103, and 104 may include a wheel key 102 disposed on the front surface 110A of the housing 110 and rotatable in at least one direction, and/or key buttons 102 and 103 disposed on the side surface 110C of the housing 110. For example, the wheel key 102 may have a shape corresponding to the shape of the front plate 101. In another embodiment, the electronic device 100 may not include some or all of the aforementioned key input devices 102, 103, and 104. For example, the electronic device 100 may not include the wheel key 102. In an embodiment, the wheel key 102 that is not included may be implemented in another form, such as a soft key on the display 120.

The connector hole 109 may accommodate a connector (e.g., a USB connector) for transmitting and receiving power and/or data with an external electronic device. The electronic device 100 may further include, for example, a connector cover (not illustrated) that covers at least a portion of the connector hole 109 and blocks inflow of foreign substances into the connector hole. In another embodiment, the electronic device 100 may not include the connector hole 109, and in this case, the electronic device 100 may transmit and receive power and/or data with an external electronic device using wireless communication.

In an embodiment, the fastening members 150 and 160 may be detachably fastened to at least a partial area of the housing 110 using locking members 151 and 161. For example, the fastening members 150 and 160 may include at least one of a fixing member 152, a fixing member fastening hole 153, a band guide member 154, and a band keeper 155.

The fixing member 152 may be configured to fix the housing 110 and the fastening members 150 and 160 to a part of the body (e.g., a wrist and the like) of the user. The fixing member fastening hole 153 may correspond to the fixing member 152 and may fix the housing 110 and the fastening members 150 and 160 to the part of the body of the user. The band guide member 154 may allow the fastening members 150 and 160 to be closely fastened to the part of the body of the user by being configured to limit a movement range of the fixing member 152 when the fixing member 152 is fastened to the fixing member fastening hole 153. The band keeper 155 may limit a movement range of the fastening members 150 and 160 in a state in which the fixing member 152 and the fixing member fastening hole 153 are fastened.

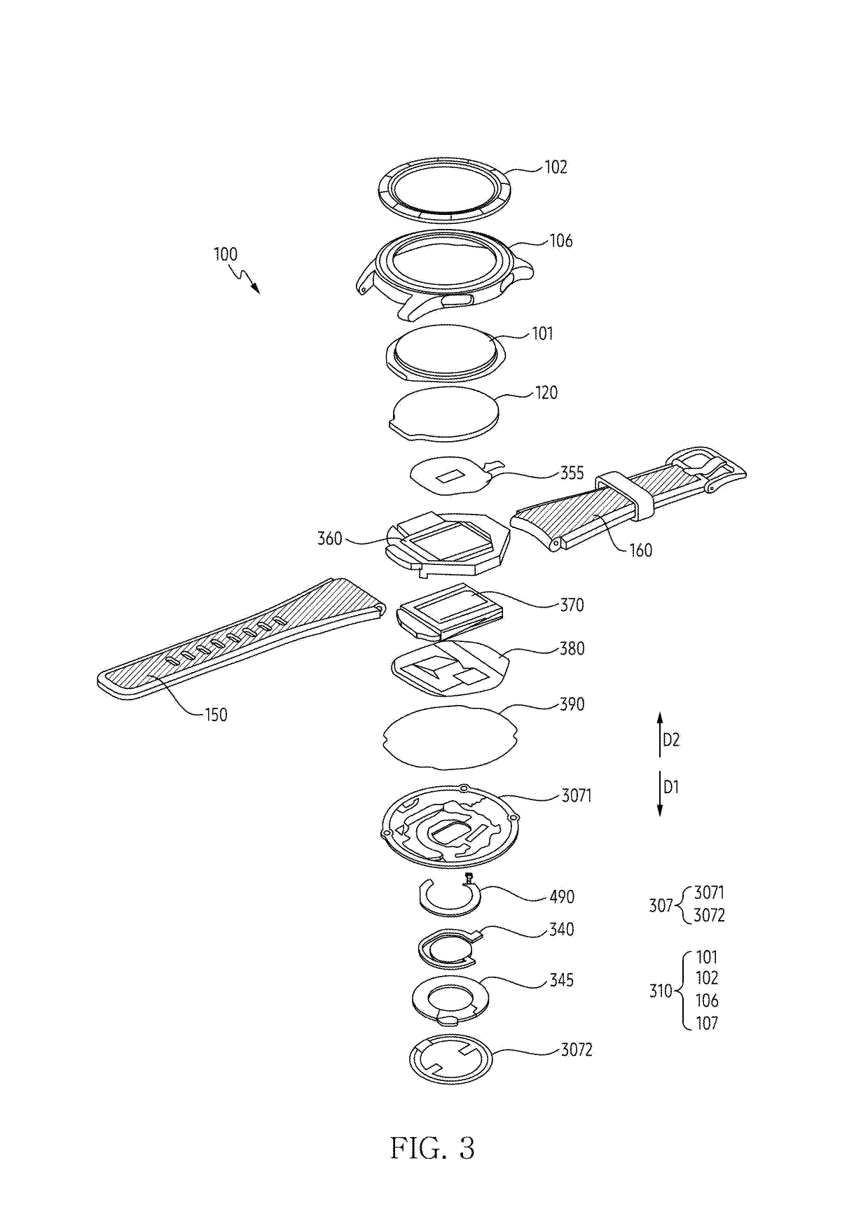

FIG. 3 is an exploded perspective view of an electronic device 100 according to an embodiment of the disclosure.

A first direction D1 illustrated may be substantially perpendicular to a front plate 101 and be a direction from the front plate 101 toward a rear plate 307, and a second direction D2 may be the opposite direction of the first direction D1. Hereinafter, a redundant description of a configuration having the same reference numeral as the aforementioned configuration may be omitted.

Referring to FIG. 3, the electronic device 100 may include a housing 310, an antenna 355, a bracket 360, a battery 370, a printed circuit board (PCB) 380, a sealing member 390, a wireless charging coil 345, and a sensor module 340.

In an embodiment, the housing 310 (e.g., the housing 110 of FIGS. 1 and 2) may include a wheel key 102, the front plate 101, the rear plate 307, and a frame 106 that form an exterior of the electronic device 100 (e.g., the front surface 110A, the rear surface 110B, and the side surface 110C of FIGS. 1 and 2). In another embodiment, the housing 310 of the electronic device 100 may not include the wheel key 102, and in this case, the front surface of the electronic device 100 may be formed by the front plate 101, or the front plate 101 and the frame 106 together may form the front surface.

In an embodiment, the rear plate 307 (e.g., the rear plate 107 of FIGS. 1 and 2) may include a first plate 3071 and a second plate 3072. The second plate 3072 may be disposed below the first plate 3071 (e.g., in the first direction D1). The first plate 3071 may be connected to the frame 106. The second plate 3072 may be connected to the first plate 3071 to close a hollow formed in the first plate 3071.

In an embodiment, the bracket 360 may be disposed inside the housing 310. For example, the bracket 360 may be disposed inside the frame 106. The bracket 360 may be located between the display 120 and the PCB 380. For example, the display 120 may be disposed on a surface of the bracket 360 (e.g., a surface facing the second direction D2), and the PCB 380 may be disposed on another surface (e.g., a surface facing the first direction D1). The bracket 360 may support the display 120 and the PCB 380. The bracket 360 may be formed of a metal material and/or a non-metal material (e.g., polymer).

In an embodiment, the PCB 380 may be equipped with a processor (e.g., a processor 1220 of FIG. 12), memory (e.g., memory 1230 of FIG. 12), and/or an interface (e.g., an interface 1277 of FIG. 12). The processor may include, for example, one or more of a central processing unit, an application processor, a graphics processing unit (GPU), an application processor sensor processor, or a communication processor. The memory may include, for example, volatile memory or non-volatile memory. The interface may include, for example, a high definition multimedia interface (HDMI), a universal serial bus (USB) interface, a secure digital (SD) card interface, and/or an audio interface. The interface may, for example, electrically or physically connect the electronic device 100 to an external electronic device, and may include a USB connector, an SD card/multimedia card (MMC) connector, or an audio connector.

In an embodiment, the battery 370 may be a device for supplying power to at least one component of the electronic device 100 and may include, for example, a rechargeable secondary battery. The battery 370 may be accommodated in a space formed within the bracket 360 and may be located between the bracket 360 and the PCB 380.

In an embodiment, the antenna 355 may be disposed between the display 120 and the bracket 360. For example, the antenna 355 may be attached to a back surface of the display 120, but is not limited thereto. The antenna 355 may include, for example, a near field communication (NFC) antenna, and/or a magnetic secure transmission (MST) antenna. The antenna 355 may, for example, perform near field communication with an external device or transmit a magnetic-based signal including a near field communication signal or payment data. In another embodiment, the antenna 355 may be disposed on the PCB 380. For example, the antenna 355 may be formed in a shape of a chip and mounted on the PCB 380.

In an embodiment, the sealing member 390 may be interposed between the frame 106 and the first plate 3071 of the rear plate 307. The sealing member 390 may be configured to block moisture and foreign substances from flowing in between the frame 106 and the first plate 3071 from the outside.

In an embodiment, the wireless charging coil 345 configured to transmit and receive a power signal with an external device may be disposed between the first plate 3071 and the second plate 3072. For example, a hollow aligned with the hollow formed in the first plate 3071 may be formed in the wireless charging coil 345.

In an embodiment, the sensor module 340 may be disposed between the first plate 3071 and the second plate 3072. The sensor module 340 may be disposed in a form that is at least partially accommodated within the hollow of the wireless charging coil 345. The sensor module 340 may at least partially face the second plate 3072. For example, the sensor module 340 may be disposed to face the second plate 3072. The sensor module 340 may detect the biometric information of a user through the second plate 3072. For example, the sensor module 340 may include an optical sensor for detecting a heart rate and/or oxygen saturation of the user in contact with the second plate 3072. In this case, the second plate 3072 may be formed of a material that is at least partially optically transmissive (e.g., substantially transparent resin and/or glass).

In an embodiment, a conductive member 490 may be located between the PCB 380 and the second plate 3072.

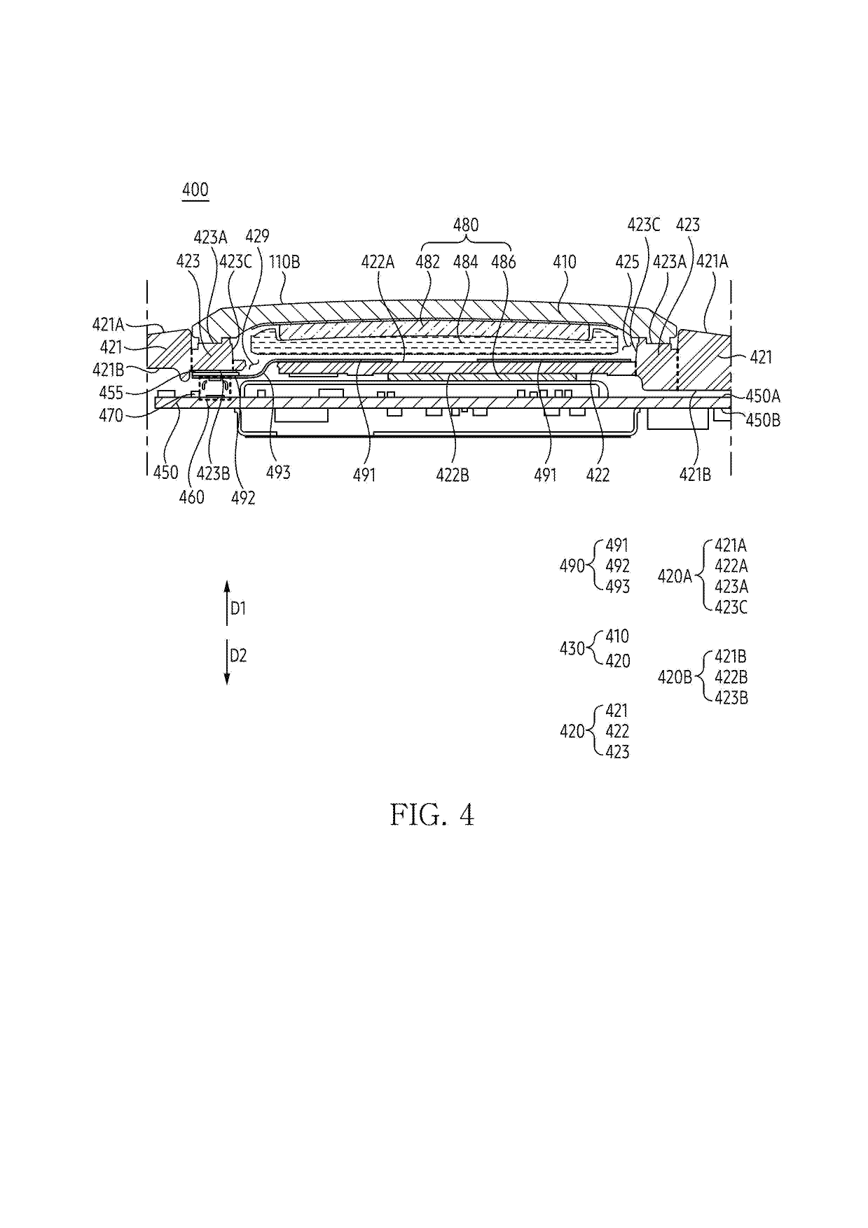

FIG. 4 is a cross-sectional view of an electronic device according to an embodiment of the disclosure.

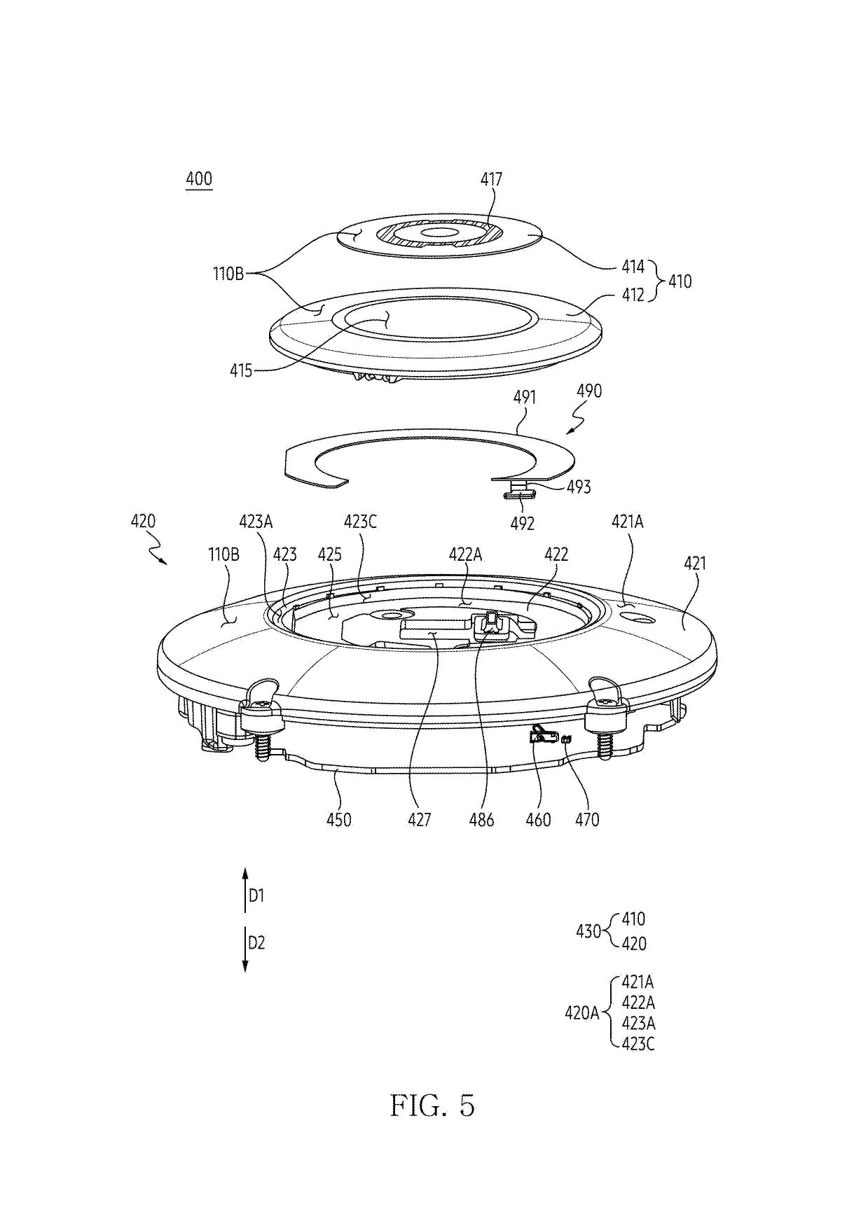

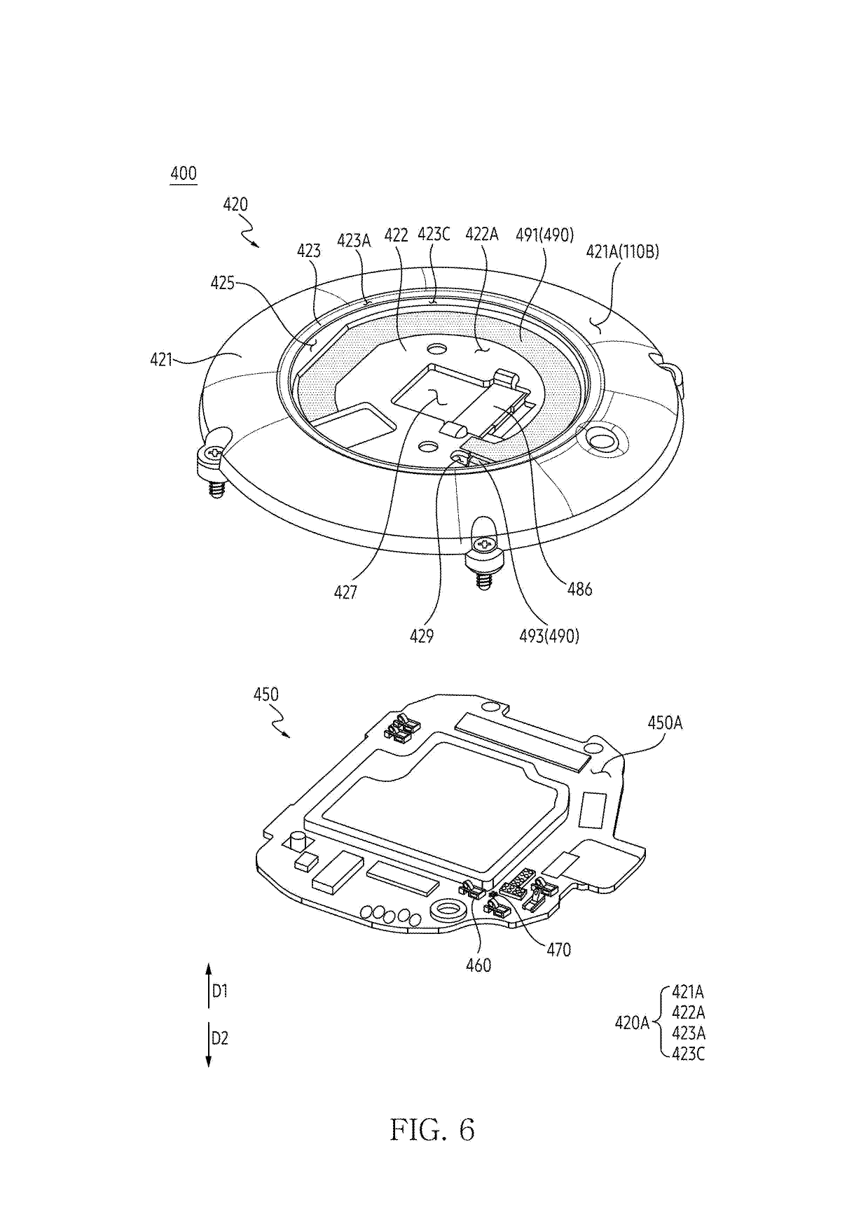

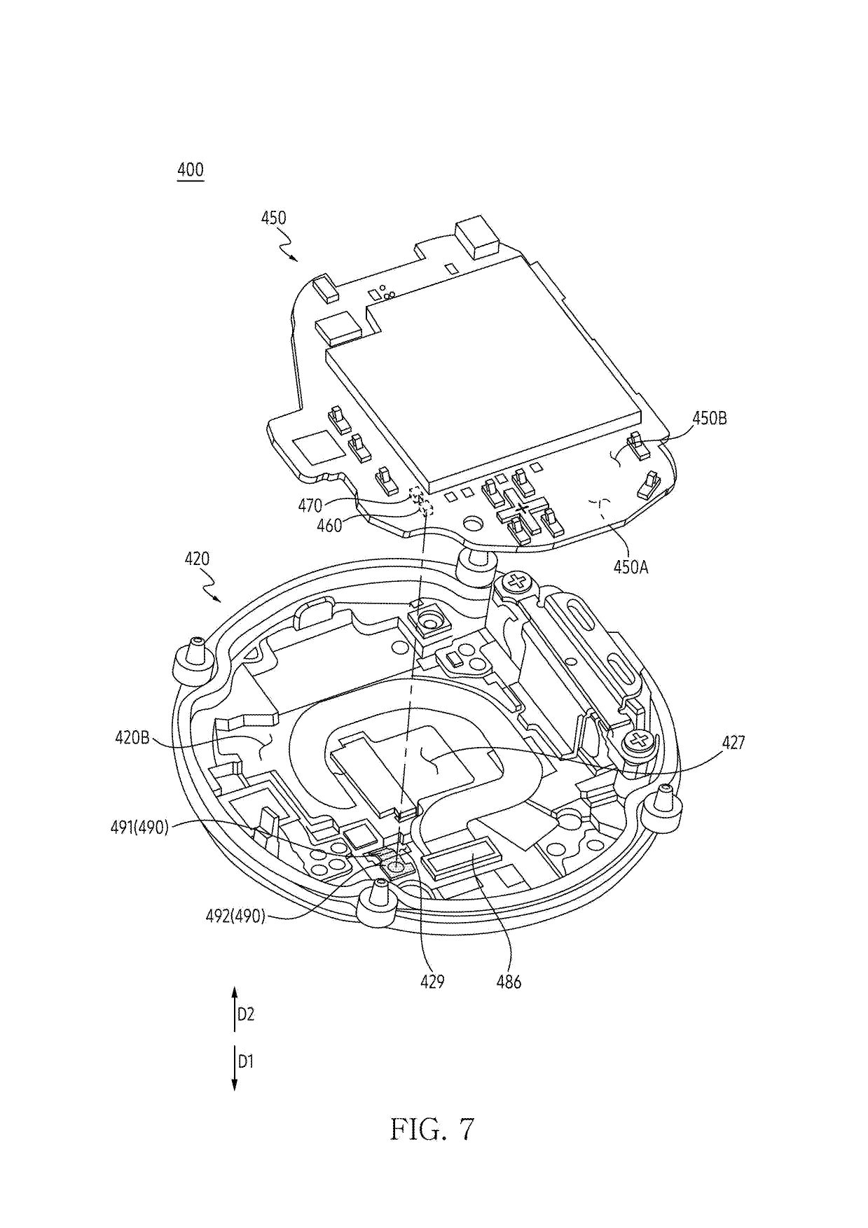

FIGS. 5, 6, and FIG. 7 are exploded views illustrating a partial configuration of an electronic device according to various embodiments of the disclosure.

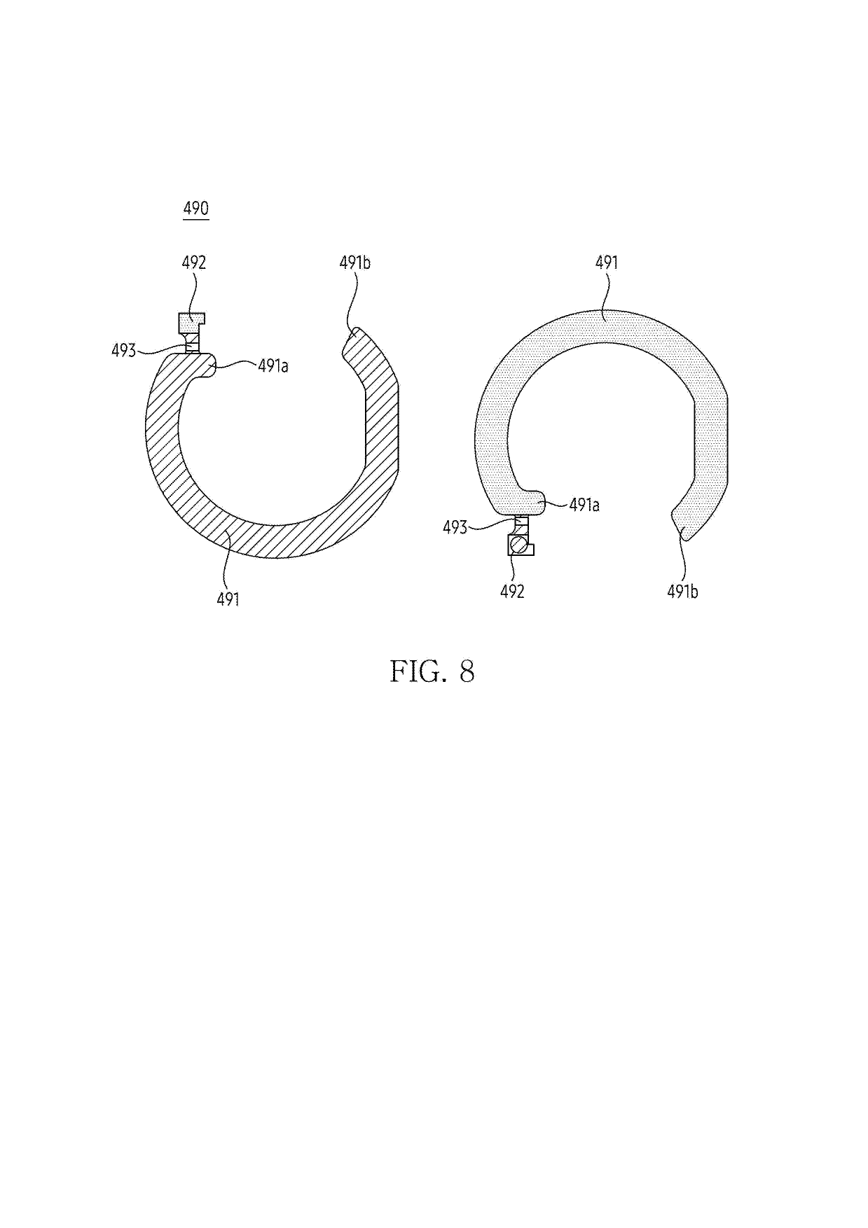

FIG. 8 is a drawing illustrating both surfaces of a conductive member according to an embodiment of the disclosure.

Referring to FIGS. 4, 5, 6, 7, and FIG. 8, an electronic device 400 (e.g., the electronic device 300 of FIG. 3) according to an embodiment may include a rear cover 430 (e.g., the rear plate 307 of FIG. 3), a printed circuit board (PCB) 450 (e.g., the printed circuit board 380 of FIG. 3), a protection circuit 470, a conductive member 490, a connector 460, and wireless charging circuitry 480 (e.g., the wireless charging coil 385 of FIG. 3).

In an embodiment, the rear cover 430 may at least partially form a rear surface 110B of the electronic device 400. For example, the rear cover 430 may include a first cover 410 and a second cover 420. For example, the first cover 410 of the rear cover 430 may form a portion of the rear surface 110B, and the second cover 420 may form another portion of the rear surface 110B. In this regard, the rear cover 430 may be included in a housing (e.g., the housing 310 of FIG. 3) of the electronic device 400. For example, the first cover 410 may be disposed on the second cover 420 (e.g., in a first direction D1). For example, the first cover 410 may be coupled to the second cover 420 to cover a recess 425 of the second cover 420. The first cover 410 may be at least partially formed of a conductive material (e.g., metal). For example, the first cover 410 may include a first member 412 formed of a conductive metal and a second member 414 formed of a non-conductive material (e.g., glass). For example, the first member 412 and the second member 414 may be formed in a plate shape, but is not limited thereto. For example, the second member 414 may be coupled to the first member 412 to close a hollow 415 formed in the first member 412. A conductive layer (or metal layer) 417 may be formed on the second member 414. In an embodiment, the conductive layer 417 may include a layer on which a conductive metal is deposited, but is not limited thereto. In an embodiment, the first cover 410 may be referred to as a metal cover in that it is at least partially formed of a conductive material. In addition, the first member 412 of the first cover 410 may be referred to as a metal cover in that it may include a conductive material.

In an embodiment, the second cover 420 may include a first surface 420A and a second surface 420B opposite to the first surface 420A. The first surface 420A may face a direction toward the first cover 410. The second surface 420B may face a direction toward the PCB 450.

In an embodiment, the first surface 420A of the second cover 420 may include a first surface 421A of a first part 421, a first surface 422A of a second part 422, a first surface 423A of a third part 423, and a side surface 423C of the third part 423. The first surface 422A of the second part 422 may be spaced apart from the first cover 410. The side surface 423C of the third part 423 may extend from an outer edge of the first surface 422A of the second part 422 to an inner edge of the first surface 423A of the third part 423. The side surface 423C of the third part 423 may extend from the PCB 450 in a direction toward the first cover 410. The first cover 410 may be disposed on at least a portion of the first surface 423A of the third part 423. The first surface 421A of the first part 421 may extend from an outer edge of the first surface 423A of the third part 423.

In an embodiment, the second surface 420B of the second cover 420 may include a second surface 421B of the first part 421, a second surface 422B of the second part 422, and a second surface 423B of the third part 423. The second surface 423B of the third part 423 may extend from an outer edge of the second surface 422B of the second part 422 to an inner edge of the second surface 421B of the first part 421.

In an embodiment, the recess 425 may be formed on the first surface 420A of the second cover 420. For example, the recess 425 may be formed by the second part 422 and the third part 423. For example, the recess 425 may be formed by the first surface 422A of the second part 422 and the side surface 423C of the third part 423. The side surface 423C may at least partially form a depth of the recess 425. The recess 425 may be covered by the first cover 410. In an embodiment, a first portion 491 of the conductive member 490 may include a shape extending along the side surface 423C of the recess 425 when viewed from above (e.g., when viewed in a second direction D2).

In an embodiment, the second cover 420 may include the first part 421 forming the portion of the rear surface 110B, the second part 422 spaced apart from the first part 421, and the third part 423 connecting the first part 421 and the second part 422. The first part 421 may form the portion of the rear surface 110B of the electronic device 400 by being exposed to the outside. For example, the first surface 421A of the first part 421 may form the portion of the rear surface 110B. As the first cover 410 covers the second part 422 and the third part 423, the first cover 410 may form another portion of the rear surface 110B, and the second part 422 and the third part 423 may not be exposed to the outside. The second part 422 may support the first portion 491 of the conductive member 490. For example, the first portion 491 of the conductive member 490 may be supported by the first surface 422A of the second part 422. The second part 422 may be referred to as a support portion of the second cover 420. For example, the third part 423 may support the first cover 410. For example, the first cover 410 may be supported by the first surface 423A of the third part 423.

In an embodiment, the second cover 420 may include a first hole 427 and/or a second hole 429 formed in the second part 422. For example, each of the first hole 427 and the second hole 429 may extend from the first surface 422A to the second surface 422B of the second part 422 to pass through the second part 422. For example, the second hole 429 may be located between an outer edge of the first surface 422A of the second part 422 (or the side surface 423C of the third part 423) and the first hole 427 when viewed from above (e.g., when viewed in the first direction D1). In an embodiment, a connection member 486 of the wireless charging circuitry 480 may pass through the first hole 427. In an embodiment, the conductive member 490 may pass through the second hole 429. For example, the second cover 420 may be at least partially formed of a non-conductive material (e.g., resin).

In an embodiment, the electronic device 400 may obtain biometric information using the first member 412 and/or the conductive layer 417. For example, the electronic device 400 may include a sensor (or sensor circuitry) configured to detect biometric information of a user using the first member 412 and/or the conductive layer 417. The first member 412 and/or the conductive layer 417 may operate as an electrode that transmits and receives an electrical signal with a body of a user in contact with the housing of the electronic device 400, and the sensor may detect a biometric signal of the user based on a signal received through the electrode. For example, the biometric signal may include an electrical signal based on a bioelectrical impedance analysis (BIA) for measuring a body composition of the user, but is not limited thereto.

In an embodiment, the PCB 450 may be disposed within the housing. The PCB 450 may include a first surface 450A facing the rear cover 430 and a second surface 450B opposite to the first surface 450A. The PCB 450 may include a conductive region providing a ground for at least one component of the electronic device 400. The conductive region may be formed of, for example, a conductive material (e.g., copper).

In an embodiment, the protection circuit 470 may be disposed on the PCB 450. For example, the protection circuit 470 may be disposed on the first surface 450A of the PCB 450. The protection circuit 470 may be connected between the conductive member 490 and the conductive region of the PCB 450. The conductive member 490 may be electrically connected to the conductive region of the PCB 450 through the protection circuit 470. For example, the PCB 450 may include a conductive line connected to the conductive member 490 (or the connector 460). The protection circuit 470 may be connected in series to the conductive line. For example, the conductive member 490 may be connected to the connector 460 on the PCB 450, the connector 460 may be connected to the protection circuit 470 through the conductive line of the PCB 450, and the protection circuit 470 may be connected to the conductive region through the conductive line. As such, the conductive member 490, the connector 460, and the protection circuit 470 may be connected in series to the conductive region of the PCB 450 in order, but is not limited thereto. For example, the conductive member 490 and the protection circuit 470 may also be connected in parallel with respect to the conductive region of the PCB 450. For example, the protection circuit 470 may configure a shunt device (or shunt circuitry) for the conductive member 490 connected to the conductive line, by being connected in parallel to the conductive line. In this case, the conductive line may connect the conductive member 490 to a terminal (e.g., an input/output terminal) of other circuitry instead of the conductive region, but is not limited thereto. In a case in which the conductive line is connected to the terminal of the other circuitry, a signal associated with the terminal may be transmitted through the conductive line. The protection circuit 470 may include, for example, a shock protector-type element such as a transient voltage suppressor (TVS) diode or a varistor.

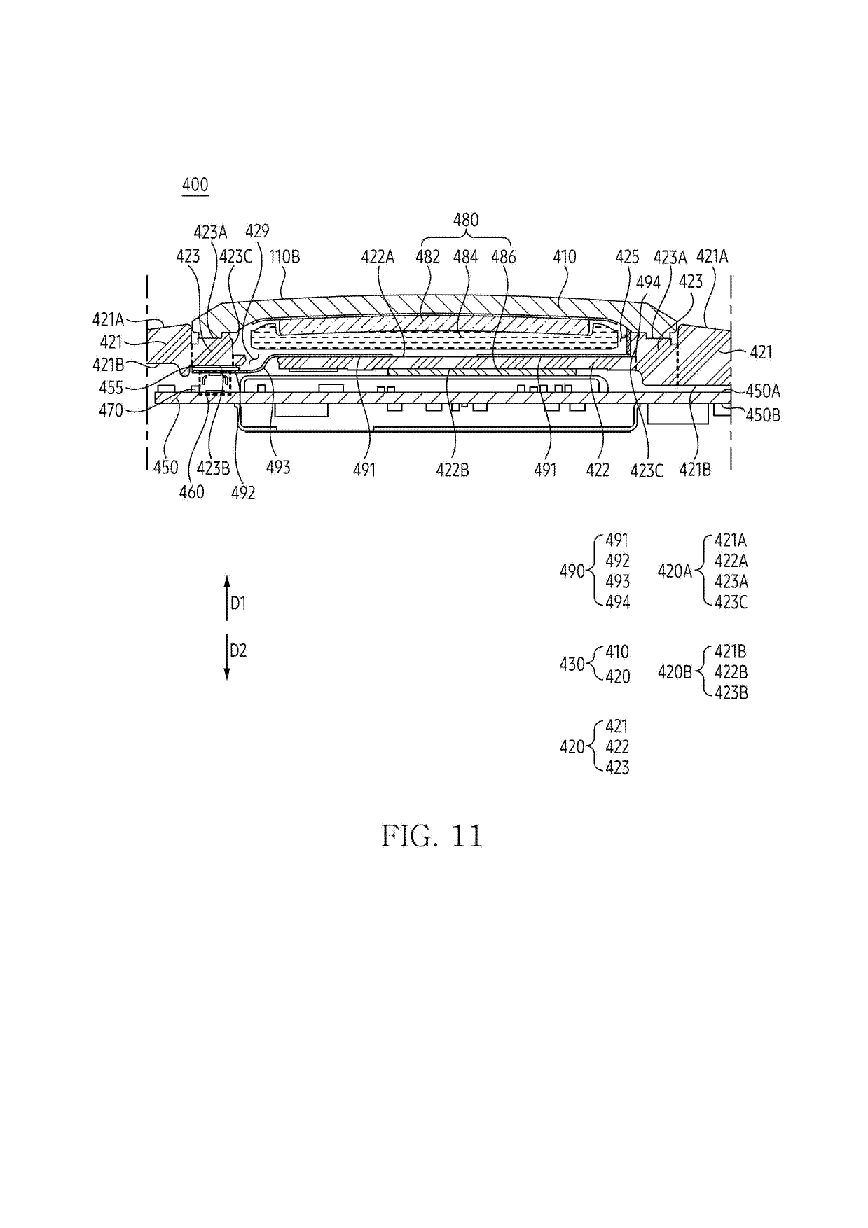

In an embodiment, the conductive member 490 may be disposed between the PCB 450 and the first cover 410. In an embodiment, the conductive member 490 may be disposed between the wireless charging circuitry 480 and the PCB 450. The conductive member 490 may be electrically connected to the conductive region of the PCB 450. For example, the conductive member 490 may at least partially overlap the first cover 410 when viewed in a direction perpendicular to the PCB 450 (e.g., the first direction D1). For example, the conductive member 490 may at least partially overlap a wireless charging coil 482 and a shielding member 484 when viewed in the direction perpendicular to the PCB 450 (e.g., the first direction D1). In FIG. 4, an outer edge of the first portion 491 of the conductive member 490 is illustrated as being located further outward than the shielding member 484, but is not limited by the illustrated example. For example, at least a portion of the outer edge of the first portion 491 of the conductive member 490 may be located inward of the shielding member 484. The conductive member 490 may not be directly electrically connected to a conductive portion (e.g., the first member 412 of the first cover 410) of the rear cover 430, but is not limited thereto. For example, as illustrated in FIG. 11, the conductive member 490 may further include a fourth portion 494 that electrically connects the first portion 491 to the first cover 410.

In an embodiment, the conductive member 490 may be at least partially formed of a conductive material. For example, the conductive member 490 may include a conductive pattern formed on a carrier using laser direct structuring (LDS), a conductive pattern of a flexible PCB, a conductive material deposited or plated on a substrate, a conductive metal sheet, a conductive metal film, or a conductive metal foil. The conductive member 490 may be formed to be at least partially bendable. For example, a third portion 493 of the conductive member 490 may be formed to be bendable. For example, the conductive member 490 may be referred to as a conductor. Additionally or optionally, the conductive member 490 may include a protection member surrounding the conductive material.

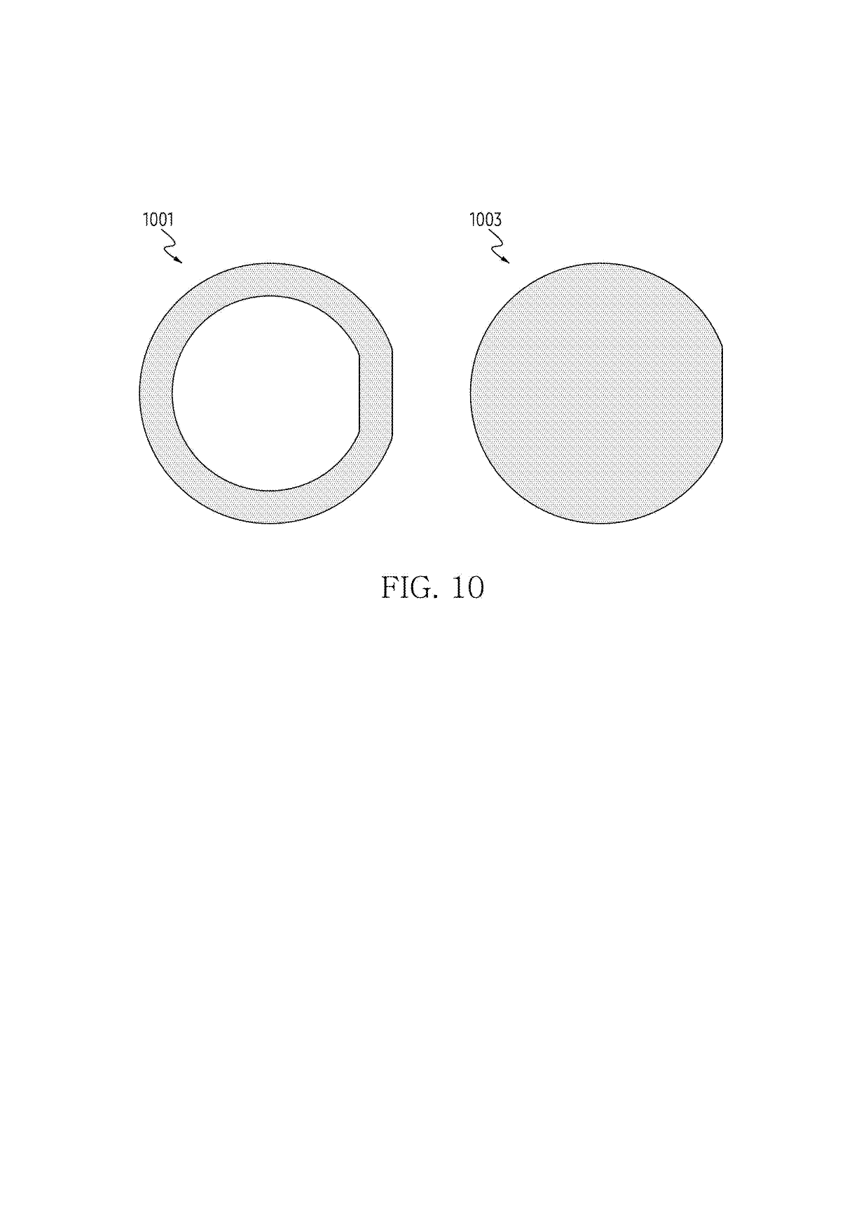

In an embodiment, the conductive member 490 may include the first portion 491, a second portion 492, and the third portion 493. In an embodiment, the first portion 491 may be disposed between the first cover 410 and the second cover 420. For example, the first portion 491 may be disposed between the second part 422 of the second cover 420 and the first cover 410. The first portion 491 may be supported by the first surface 420A of the second cover 420. The first portion 491 may be disposed on the first surface 420A of the second cover 420. For example, the first portion 491 may be disposed within the recess 425 and may be disposed on the first surface 422A of the second part 422. The first portion 491 may, for example, be attached onto the first surface 422A of the second part 422 through an adhesive member (e.g., a double-sided tape). In an embodiment, the first portion 491 may include a shape that at least partially surrounds an edge of the first hole 427 when viewed in the direction perpendicular to the PCB 450 (e.g., the second direction D2). For example, a hollow in which at least a portion is open may be formed in the first portion 491, and the first hole 427 may be disposed to be located within the hollow. For example, the first portion 491 may be formed in an annular shape that at least partially surrounds the first hole 427 when viewed from above. For example, as illustrated in FIG. 8, the first portion 491 of the conductive member 490 may be formed in an open annular shape in some section such that both ends 491a and 491b are formed. The third portion 493 may extend from a first end 491a of the both ends 491a and 491b of the first portion 491. However, the shape of the first portion 491 is not limited by the illustrated example, and examples of various shapes of the first portion 491 will be described below with reference to FIG. 10.

In an embodiment, the second portion 492 may be disposed between the second cover 420 and the PCB 450. For example, the second portion 492 may be disposed between the third part 423 of the second cover 420 and the PCB 450. For example, the second portion 492 may be disposed between the second surface 423B of the third part 423 and the first surface 450A of the PCB 450. The second portion 492 may be disposed on the PCB 450. For example, the second portion 492 may be disposed on the first surface 450A of the PCB 450. The second portion 492 may be connected to the connector 460 on the PCB 450. The second portion 492 may be supported by the third part 423 of the second cover 420. For example, the second portion 492 may be supported by the second surface 423B of the third part 423. The second portion 492 may be stably connected to the connector 460 as the second portion 492 is supported by the third part 423. An adhesive member 455 (e.g., a double-sided tape) may be interposed between the third part 423 of the second cover 420 and the second portion 492. Alternatively, the first portion 491 may be at least partially disposed between the second part 422 of the second cover 420 and the PCB 450. For example, the entirety of the first portion 491 may be attached to the second surface 422B of the second part 422. In this case, the conductive member 490 may not include the third portion 493 passing through the second part 422, and the second portion 492 may directly extend from the first portion 491. For example, a portion of the first portion 491 may be attached to the second surface 422B of the second part 422. In this case, the third portion 493 may connect the portion of the first portion 491 attached onto the second surface 422B of the second part 422 and the remaining portion of the first portion 491 attached onto the first surface 422A of the second part 422, but is not limited thereto.

In an embodiment, the third portion 493 may extend from the first portion 491 to the second portion 492. The third portion 493 may connect the first portion 491 and the second portion 492. The third portion 493 may pass through the second cover 420. For example, the third portion 493 may pass through the second part 422 of the second cover 420. The third portion 493 may pass through the second hole 429 formed in the third part 423.

In an embodiment, the connector 460 may be disposed on a surface (e.g., the first surface 450A) of the PCB 450. The connector 460 may be electrically connected to the protection circuit 470. As the second portion 492 of the conductive member 490 is connected to the connector 460, the conductive member 490 may be electrically connected to the protection circuit 470. In an embodiment, the connector 460 may include a C-clip connector in contact with the second portion 492 of the conductive member 490, but is not limited thereto.

In an embodiment, the wireless charging circuitry 480 may include the wireless charging coil 482 (e.g., the wireless charging coil 385 of FIG. 3) disposed on the first cover 410 (e.g., in the second direction D2), the shielding member 484 disposed on the first cover 410 to cover the wireless charging coil 482, and/or the connection member 486 for connecting the wireless charging coil 482 to the PCB 450. The wireless charging coil 482 may generate a current induced from a magnetic field generated by a transmission coil of an external device. The shielding member 484 may improve power transmission and reception efficiency by concentrating the magnetic field to the wireless charging coil 482. The shielding member 484 may include a magnetic material to shield the magnetic field. For example, the shielding member 484 may be formed of ferrite, but is not limited thereto. The connection member 486 may include a flexible PCB, but is not limited thereto.

An electrostatic discharge (ESD) component may flow into the electronic device 400 through the conductive portion (e.g., the first member 412) of the rear cover 430. An ESD component with a certain intensity or higher may cause malfunction and damage to components on the PCB 450. For example, an ESD component may cause a lock-up or a reboot of an application processor (e.g., a processor 1220 of FIG. 12) disposed on the PCB 450. A wearable device such as the electronic device 400 may be particularly vulnerable to ESD. For example, as the electronic device 400 is continuously rubbed against a body of a user or clothing of the user, static electricity may be easily generated, and the accumulated static electricity due to this may discharge into the electronic device 400. In addition, due to the trend of miniaturizing the electronic device 400 for portability and the increasing complexity and density of internal electronic components to provide more various functions to a user, it is becoming more vulnerable to electrostatic discharge.

The conductive member 490 according to an embodiment may prevent a problem caused by ESD by forming an electrostatic discharge induction path. For example, an ESD component flowing through the first cover 410 may flow into the conductive member 490 disposed between the first cover 410 and the PCB 450. The ESD component that has flowed into the conductive member 490 may be induced to the protection circuit 470 connected to the conductive member 490 and to the conductive region of the PCB 450.

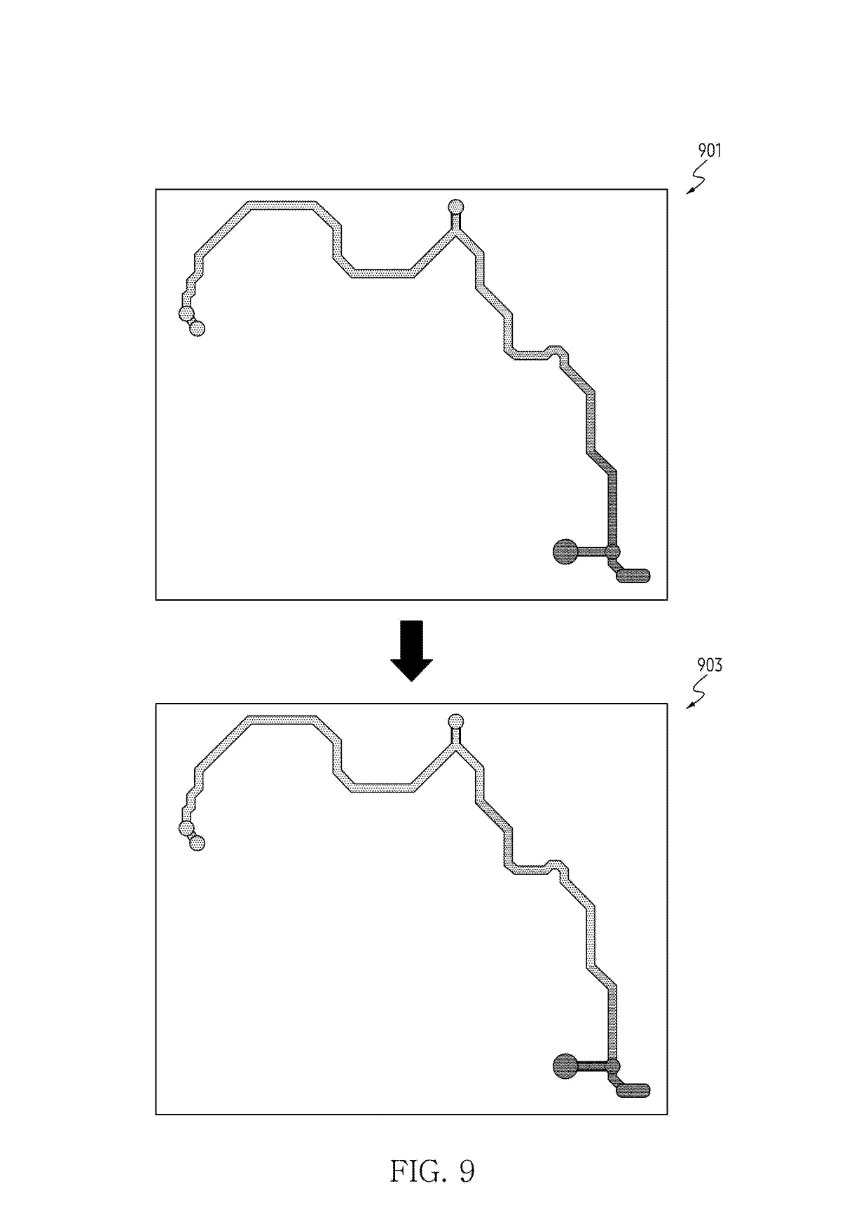

FIG. 9 is a drawing illustrating an ESD prevention effect by a conductive member according to an embodiment of the disclosure.

Reference numerals 901 and 903 of FIG. 9 indicate intensity of a magnetic field (H-field) of wiring connected to the application processor. The wiring may be a signal line, an interrupt signal line, or a power supply (PS)-HOLD wiring of the application processor. In FIG. 9, as the shading becomes darker, the intensity of the magnetic field increases. Reference numeral 901 is a drawing of a comparative embodiment that does not include a conductive member 490, and reference numeral 903 is a drawing of an electronic devices 400 according to an embodiment that includes the conductive member 490.

Referring to FIG. 9, the intensity of the magnetic field distributed in the wiring of the application processor may be reduced by the conductive member 490 connected to the conductive region of a printed circuit board (PCB) 450 through a protection circuit 470. The intensity of the magnetic field according to an embodiment may be approximately 46 A/m, and the intensity of the magnetic field according to the comparative embodiment may be approximately 66 A/m. For example, the conductive member 490 may prevent malfunction of the application processor by inducing an ESD component so as not to flow into the wiring of the application processor.

FIG. 10 is a drawing illustrating shapes of a conductive member according to an embodiment of the disclosure.

Referring to FIG. 10, a first portion 491 of a conductive member 490 may be formed in a closed annular shape, as indicated by reference numeral 1001. Alternatively, the first portion 491 of the conductive member 490 may be formed as a circular plate that does not include a hollow, as indicated by reference numeral 1003.

FIG. 11 is a cross-sectional view of an electronic device according to an embodiment of the disclosure.

Referring to FIG. 11, a conductive member 490 according to an embodiment may further include a fourth portion 494. The fourth portion 494 may extend from a first portion 491 to a first cover 410. For example, the fourth portion 494 may extend from the first portion 491 to a first member 412 of the first cover 410. The fourth portion 494 may electrically connect the conductive member 490 to the first cover 410 (e.g., a conductive portion of the first cover 410). As the conductive member 490 is directly electrically connected to the first cover 410, which causes ESD components, ESD protection may be improved.

A wearable device (e.g., the electronic device 400 of FIG. 4) according to an embodiment may comprise a housing (e.g., the housing 310 of FIG. 3) including a metal cover (e.g., the first member 412 of FIG. 5), a printed circuit board (PCB) (e.g., the printed circuit board 450 of FIG. 4) within the housing, a protection circuit (e.g., the protection circuit 470 of FIG. 4) disposed on the PCB, and a conductive member (e.g., the conductive member 490 of FIG. 4) disposed between the PCB and the metal cover. The protection circuit may be electrically connected to a ground of the PCB. The conductive member may be electrically connected to the protection circuit to form an electrostatic discharge induction path. Accordingly, it is possible to prevent malfunction of the wearable device or damage to an internal component caused by electrostatic discharge.

In an embodiment, the conductive member may overlap the metal cover based on a direction perpendicular to the PCB (e.g., the first direction D1 of FIG. 4).

In an embodiment, the metal cover may be a first cover (e.g., the first cover 410 of FIG. 4). The housing may include a second cover (e.g., the second cover 420 of FIG. 4). The second cover may include a first surface (e.g., the first surface 420A of FIG. 4) facing the first cover and a second surface (e.g., the second surface 420B of FIG. 4) opposite to the first surface and facing the PCB. A recess (e.g., the recess 425 of FIG. 4) may be formed on the first surface of the second cover. The first cover may be disposed on the first surface of the second cover to cover the recess. A first portion (e.g., the first portion 491 of FIG. 4) of the conductive member may be disposed on the first surface of the second cover within the recess.

In an embodiment, the recess of the second cover may include a bottom surface (e.g., the first surface 422A of the second part 422 of FIG. 4) on which the first portion of the conductive member is disposed, and a side surface (e.g., the side surface 423C of the third part 423 of FIG. 4) extending from an outer edge of the bottom surface in a direction toward the first cover. The first portion of the conductive member may extend along the outer edge of the bottom surface when viewed in a direction perpendicular to the PCB.

In an embodiment, a first hole (e.g., the first hole 427 of FIG. 5) extending from the bottom surface to the second surface to pass through the second cover may be formed. The first portion of the conductive member may be formed in an annular shape at least partially surrounding an edge of the first hole when viewed in a direction perpendicular to the PCB.

In an embodiment, the first portion of the conductive member may be formed in an annular shape with both ends (e.g., the both ends 921a and 921b of FIG. 8) open to surround exclusively a portion of the edge of the first hole when viewed in a direction perpendicular to the PCB.

In an embodiment, a second hole (e.g., the second hole 429 of FIG. 4) extending from the bottom surface to the second surface to pass through the second cover may be formed. The second hole may be located between the first hole and the outer edge of the bottom surface. The conductive member may include a second portion (e.g., the second portion 492 of FIG. 4) connected to the PCB and a third portion (e.g., the third portion 493 of FIG. 4) passing through the second hole and extending from the first portion to the second portion.

The wearable device according to an embodiment may comprise a connector (e.g., the connector 460 of FIG. 4) disposed on the PCB and electrically connected to the protection circuit. As the second portion of the conductive member is connected to the connector, the conductive member may be electrically connected to the protection circuit.

In an embodiment, the PCB may include a first surface (e.g., the first surface 450A of FIG. 4) facing the second cover and a second surface (e.g., the second surface 450B of FIG. 4) opposite to the first surface of the PCB. The connector may be disposed on the first surface of the PCB.

In an embodiment, the second portion of the conductive member may be supported by the second surface of the second cover.

In an embodiment, the connector may include a C-clip connector. The second portion of the conductive member may be in contact with the C-clip connector.

In an embodiment, the second cover may include a first part (e.g., the first part 421 of FIG. 4) forming a portion of a rear surface 110B of the wearable device, a second part (e.g., the second part 422 of FIG. 4) spaced apart from the first part and defining the bottom surface of the recess, and a third part (e.g., the third part 423 of FIG. 4) extending from the first part to the second part. The first cover may form another portion of the rear surface by covering the second part and the third part of the second cover. The first surface of the second cover may include a first surface (e.g., the first surface 423A of FIG. 4) of the third part. The second surface of the second cover may include a second surface (e.g., the second surface 423B of FIG. 4) of the third part. The first surface of the third part may support the first cover. The second surface of the third part may support the second portion of the conductive member.

The wearable device according to an embodiment may comprise a wireless charging coil (e.g., the wireless charging coil 482 of FIG. 4) within the housing, disposed on the metal cover, and a shielding member (e.g., the shielding member 484 of FIG. 4) within the housing, disposed on the metal cover to cover the wireless charging coil. The conductive member may be located between the PCB and the shielding sheet.

In an embodiment, the second cover may be formed of a non-conductive material.

In an embodiment, the protection circuit may include an ESD element, a protection device, a transient voltage suppressor (TVS) diode, or a varistor.

The wearable device according to an embodiment may comprise a sensor configured to detect biometric information of a user using the metal cover.

The wearable device according to an embodiment may comprise a third cover (e.g., the second member 414 of FIG. 5) coupled to the metal cover to close a hollow (e.g., the hollow 415 of FIG. 5) formed in the metal cover. The third cover may include a glass plate and a metal layer (e.g., the conductive layer 417 of FIG. 5) deposited on the glass plate.

In an embodiment, the metal cover may not be directly electrically connected to the conductive member.

A wearable device (e.g., the electronic device 400 of FIG. 4) according to an embodiment may comprise a housing (e.g., the housing 310 of FIG. 3) including a first cover (e.g., the first cover 410 of FIG. 4) including a conductive portion, a printed circuit board (PCB) (e.g., the printed circuit board 450 of FIG. 4) within the housing, a protection circuit (e.g., the protection circuit 470 of FIG. 4) on the PCB, a sensor within the housing configured to detect biometric information of a user using the conductive portion of the first cover, and a conductive member disposed between the PCB and the first cover to overlap the conductive portion. The protection circuit may be electrically connected to a ground of the PCB. The conductive member may be electrically connected to the protection circuit to form a path for electrostatic discharge by the conductive portion. Accordingly, it is possible to prevent malfunction of the wearable device or damage to an internal component caused by electrostatic discharge.

The wearable device according to an embodiment may comprise a connector (e.g., the connector 460 of FIG. 4) disposed on the PCB and electrically connected to the protection circuit. The housing may include a second cover (e.g., the second cover 420 of FIG. 4) coupled to the first cover. The second cover may include a support portion (e.g., the second part 422 of FIG. 4) including a first surface (e.g., the first surface 420A of FIG. 4) facing the first cover and a second surface (e.g., the second surface 420B of FIG. 4) opposite to the first surface and facing the PCB. The conductive member may include a first portion (e.g., the first portion 491 of FIG. 4) disposed on the first surface of the support portion, a second portion (e.g., the third portion 493 of FIG. 4) extending from the first portion to pass through the support portion, and a third portion (e.g., the second portion 492 of FIG. 4) extending from the second portion to the connector and contacting the connector. The conductive member may be electrically connected to the protection circuit through the connector.

FIG. 12 is a block diagram illustrating an electronic device 1201 in a network environment 1200 according to an embodiment of the disclosure.

Referring to FIG. 12, the electronic device 1201 in the network environment 1200 may communicate with an electronic device 1202 via a first network 1298 (e.g., a short-range wireless communication network), or at least one of an electronic device 1204 or a server 1208 via a second network 1299 (e.g., a long-range wireless communication network). According to an embodiment, the electronic device 1201 may communicate with the electronic device 1204 via the server 1208. According to an embodiment, the electronic device 1201 may include a processor 1220, memory 1230, an input module 1250, a sound output module 1255, a display module 1260, an audio module 1270, a sensor module 1276, an interface 1277, a connecting terminal 1278, a haptic module 1279, a camera module 1280, a power management module 1288, a battery 1289, a communication module 1290, a subscriber identification module (SIM) 1296, or an antenna module 1297. In some embodiments, at least one of the components (e.g., the connecting terminal 1278) may be omitted from the electronic device 1201, or one or more other components may be added in the electronic device 1201. In some embodiments, some of the components (e.g., the sensor module 1276, the camera module 1280, or the antenna module 1297) may be implemented as a single component (e.g., the display module 1260).

The processor 1220 may execute, for example, software (e.g., a program 1240) to control at least one other component (e.g., a hardware or software component) of the electronic device 1201 coupled with the processor 1220, and may perform various data processing or computation. According to an embodiment, as at least part of the data processing or computation, the processor 1220 may store a command or data received from another component (e.g., the sensor module 1276 or the communication module 1290) in volatile memory 1232, process the command or the data stored in the volatile memory 1232, and store resulting data in non-volatile memory 1234. According to an embodiment, the processor 1220 may include a main processor 1221 (e.g., a central processing unit (CPU) or an application processor (AP)), or an auxiliary processor 1223 (e.g., a graphics processing unit (GPU), a neural processing unit (NPU), an image signal processor (ISP), a sensor hub processor, or a communication processor (CP)) that is operable independently from, or in conjunction with, the main processor 1221. For example, when the electronic device 1201 includes the main processor 1221 and the auxiliary processor 1223, the auxiliary processor 1223 may be adapted to consume less power than the main processor 1221, or to be specific to a specified function. The auxiliary processor 1223 may be implemented as separate from, or as part of the main processor 1221.

The auxiliary processor 1223 may control at least some of functions or states related to at least one component (e.g., the display module 1260, the sensor module 1276, or the communication module 1290) among the components of the electronic device 1201, instead of the main processor 1221 while the main processor 1221 is in an inactive (e.g., sleep) state, or together with the main processor 1221 while the main processor 1221 is in an active state (e.g., executing an application). According to an embodiment, the auxiliary processor 1223 (e.g., an image signal processor or a communication processor) may be implemented as part of another component (e.g., the camera module 1280 or the communication module 1290) functionally related to the auxiliary processor 1223. According to an embodiment, the auxiliary processor 1223 (e.g., the neural processing unit) may include a hardware structure specified for artificial intelligence model processing. An artificial intelligence model may be generated by machine learning. Such learning may be performed, e.g., by the electronic device 1201 where the artificial intelligence is performed or via a separate server (e.g., the server 1208). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1230 may store various data used by at least one component (e.g., the processor 1220 or the sensor module 1276) of the electronic device 1201. The various data may include, for example, software (e.g., the program 1240) and input data or output data for a command related thereto. The memory 1230 may include the volatile memory 1232 or the non-volatile memory 1234.

The program 1240 may be stored in the memory 1230 as software, and may include, for example, an operating system (OS) 1242, middleware 1244, or an application 1246.

The input module 1250 may receive a command or data to be used by another component (e.g., the processor 1220) of the electronic device 1201, from the outside (e.g., a user) of the electronic device 1201. The input module 1250 may include, for example, a microphone, a mouse, a keyboard, a key (e.g., a button), or a digital pen (e.g., a stylus pen).

The sound output module 1255 may output sound signals to the outside of the electronic device 1201. The sound output module 1255 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1260 may visually provide information to the outside (e.g., a user) of the electronic device 1201. The display module 1260 may include, for example, a display, a hologram device, or a projector and control circuitry to control a corresponding one of the display, hologram device, and projector. According to an embodiment, the display module 1260 may include a touch sensor adapted to detect a touch, or a pressure sensor adapted to measure the intensity of force incurred by the touch.

The audio module 1270 may convert a sound into an electrical signal and vice versa. According to an embodiment, the audio module 1270 may obtain the sound via the input module 1250, or output the sound via the sound output module 1255 or a headphone of an external electronic device (e.g., an electronic device 1202) directly (e.g., wiredly) or wirelessly coupled with the electronic device 1201.

The sensor module 1276 may detect an operational state (e.g., power or temperature) of the electronic device 1201 or an environmental state (e.g., a state of a user) external to the electronic device 1201, and then generate an electrical signal or data value corresponding to the detected state. According to an embodiment, the sensor module 1276 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1277 may support one or more specified protocols to be used for the electronic device 1201 to be coupled with the external electronic device (e.g., the electronic device 1202) directly (e.g., wiredly) or wirelessly. According to an embodiment, the interface 1277 may include, for example, a high definition multimedia interface (HDMI), a universal serial bus (USB) interface, a secure digital (SD) card interface, or an audio interface.

A connecting terminal 1278 may include a connector via which the electronic device 1201 may be physically connected with the external electronic device (e.g., the electronic device 1202). According to an embodiment, the connecting terminal 1278 may include, for example, an HDMI connector, a USB connector, an SD card connector, or an audio connector (e.g., a headphone connector).

The haptic module 1279 may convert an electrical signal into a mechanical stimulus (e.g., a vibration or a movement) or electrical stimulus which may be recognized by a user via his tactile sensation or kinesthetic sensation. According to an embodiment, the haptic module 1279 may include, for example, a motor, a piezoelectric element, or an electric stimulator.

The camera module 1280 may capture a still image or moving images. According to an embodiment, the camera module 1280 may include one or more lenses, image sensors, image signal processors, or flashes.

The power management module 1288 may manage power supplied to the electronic device 1201. According to an embodiment, the power management module 1288 may be implemented as at least part of, for example, a power management integrated circuit (PMIC).

The battery 1289 may supply power to at least one component of the electronic device 1201. According to an embodiment, the battery 1289 may include, for example, a primary cell which is not rechargeable, a secondary cell which is rechargeable, or a fuel cell.

The communication module 1290 may support establishing a direct (e.g., wired) communication channel or a wireless communication channel between the electronic device 1201 and the external electronic device (e.g., the electronic device 1202, the electronic device 1204, or the server 1208) and performing communication via the established communication channel. The communication module 1290 may include one or more communication processors that are operable independently from the processor 1220 (e.g., the application processor (AP)) and supports a direct (e.g., wired) communication or a wireless communication. According to an embodiment, the communication module 1290 may include a wireless communication module 1292 (e.g., a cellular communication module, a short-range wireless communication module, or a global navigation satellite system (GNSS) communication module) or a wired communication module 1294 (e.g., a local area network (LAN) communication module or a power line communication (PLC) module). A corresponding one of these communication modules may communicate with the external electronic device via the first network 1298 (e.g., a short-range communication network, such as Bluetooth™, wireless-fidelity (Wi-Fi) direct, or infrared data association (IrDA)) or the second network 1299 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1292 may identify and authenticate the electronic device 1201 in a communication network, such as the first network 1298 or the second network 1299, using subscriber information (e.g., international mobile subscriber identity (IMSI)) stored in the subscriber identification module 1296.

The wireless communication module 1292 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1292 may support a high-frequency band (e.g., the millimeter-wave (mmWave) band) to achieve, e.g., a high data transmission rate. The wireless communication module 1292 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1292 may support various requirements specified in the electronic device 1201, an external electronic device (e.g., the electronic device 1204), or a network system (e.g., the second network 1299). According to an embodiment, the wireless communication module 1292 may support a peak data rate (e.g., 20Gbps or more) for implementing eMBB, loss coverage (e.g., 1264dB or less) for implementing mMTC, or U-plane latency (e.g., 0.5ms or less for each of downlink (DL) and uplink (UL), or a round trip of 12ms or less) for implementing URLLC.

The antenna module 1297 may transmit or receive a signal or power to or from the outside (e.g., the external electronic device) of the electronic device 1201. According to an embodiment, the antenna module 1297 may include an antenna including a radiating element composed of a conductive material or a conductive pattern formed in or on a substrate (e.g., a printed circuit board (PCB)). According to an embodiment, the antenna module 1297 may include a plurality of antennas (e.g., array antennas). In such a case, at least one antenna appropriate for a communication scheme used in the communication network, such as the first network 1298 or the second network 1299, may be selected, for example, by the communication module 1290 (e.g., the wireless communication module 1292) from the plurality of antennas. The signal or the power may then be transmitted or received between the communication module 1290 and the external electronic device via the selected at least one antenna. According to an embodiment, another component (e.g., a radio frequency integrated circuit (RFIC)) other than the radiating element may be additionally formed as part of the antenna module 1297.

According to various embodiments, the antenna module 1297 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1201 and the external electronic device 1204 via the server 1208 coupled with the second network 1299. Each of the electronic devices 1202 or 1204 may be a device of a same type as, or a different type, from the electronic device 1201. According to an embodiment, all or some of operations to be executed at the electronic device 1201 may be executed at one or more of the external electronic devices 1202 or 1204, or the server 1208. For example, if the electronic device 1201 should perform a function or a service automatically, or in response to a request from a user or another device, the electronic device 1201, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1201. The electronic device 1201 may provide the outcome, with or without further processing of the outcome, as at least part of a reply to the request. To that end, a cloud computing, distributed computing, mobile edge computing (MEC), or client-server computing technology may be used, for example. The electronic device 1201 may provide ultra low-latency services using, e.g., distributed computing or mobile edge computing. In another embodiment, the external electronic device 1204 may include an internet-of-things (IoT) device. The server 1208 may be an intelligent server using machine learning and/or a neural network. According to an embodiment, the external electronic device 1204 or the server 1208 may be included in the second network 1299. The electronic device 1201 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. As used herein, each of such phrases as "A or B," "at least one of A and B," "at least one of A or B," "A, B, or C," "at least one of A, B, and C," and "at least one of A, B, or C," may include any one of or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively", as "coupled with," or "connected with" another element (e.g., a second element), it means that the element may be coupled with the other element directly (e.g., wiredly), wirelessly, or via a third element.

As used in connection with various embodiments of the disclosure, the term "module" may include a unit implemented in hardware, software, or firmware, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1240) including one or more instructions that are stored in a storage medium (e.g., internal memory 1236 or external memory 1238) that is readable by a machine (e.g., the electronic device 1201). For example, a processor (e.g., the processor 1220) of the machine (e.g., the electronic device 1201) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term "non-transitory" simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A wearable device comprising:
a housing including a metal cover;
a printed circuit board (PCB) within the housing;
a protection circuit disposed on the PCB; and
a conductive member disposed between the PCB and the metal cover,
wherein the protection circuit is electrically connected to a ground of the PCB, and
wherein the conductive member is electrically connected to the protection circuit to form an electrostatic discharge induction path.

2. The wearable device of claim 1, wherein the conductive member overlaps the metal cover based on a direction perpendicular to the PCB.

3. The wearable device of claim 1,
wherein the metal cover is a first cover,
wherein the housing includes a second cover,
wherein the second cover includes a first surface facing the first cover and a second surface opposite to the first surface and facing the PCB,
wherein a recess is formed on the first surface of the second cover,
wherein the first cover is disposed on the first surface of the second cover to cover the recess, and
wherein a first portion of the conductive member is disposed on the first surface of the second cover within the recess.

4. The wearable device of claim 3,
wherein the recess of the second cover includes:
a bottom surface on which the first portion of the conductive member is disposed, and
a side surface extending from an outer edge of the bottom surface in a direction toward the first cover, and
wherein the first portion of the conductive member extends along the outer edge of the bottom surface when viewed in the direction perpendicular to the PCB.

5. The wearable device of claim 4,
wherein a first hole extending from the bottom surface to the second surface to pass through the second cover is formed, and
wherein the first portion of the conductive member is formed in an annular shape at least partially surrounding an edge of the first hole when viewed in a direction perpendicular to the PCB.

6. The wearable device of claim 5, wherein the first portion of the conductive member is formed in the annular shape with both ends open to surround exclusively a portion of the edge of the first hole when viewed in the direction perpendicular to the PCB.

7. The wearable device of claim 5,
wherein a second hole extending from the bottom surface to the second surface to pass through the second cover is formed,
wherein the second hole is located between the first hole and the outer edge of the bottom surface, and
wherein the conductive member includes:
a second portion connected to the PCB, and
a third portion passing through the second hole and extending from the first portion to the second portion.

8. The wearable device of claim 7, further comprising:
a connector disposed on the PCB and electrically connected to the protection circuit,
wherein the second portion of the conductive member is connected to the connector, and
wherein the conductive member is electrically connected to the protection circuit through the connector.

9. The wearable device of claim 8,
wherein the PCB includes a first surface facing the second cover and a second surface opposite to the first surface of the PCB, and
wherein the connector is disposed on the first surface of the PCB.

10. The wearable device of claim 7, wherein the second portion of the conductive member is supported by the second surface of the second cover.

11. The wearable device of claim 8,
wherein the connector includes a C-clip connector, and
wherein the second portion of the conductive member is in contact with the C-clip connector.

12. The wearable device of claim 8,
wherein the second cover includes:
a first part forming a portion of a rear surface of the wearable device,
a second part spaced apart from the first part and defining the bottom surface of the recess, and
a third part extending from the first part to the second part,
wherein the first cover forms another portion of the rear surface by covering the second part and the third part of the second cover,
wherein the first surface of the second cover includes a first surface of the third part,
wherein the second surface of the second cover includes a second surface of the third part,
wherein the first surface of the third part supports the first cover, and
wherein the second surface of the third part supports the second portion of the conductive member.

13. The wearable device of claim 1, further comprising:
a wireless charging coil within the housing, disposed on the metal cover; and
a shielding member within the housing, disposed on the metal cover to cover the wireless charging coil,
wherein the conductive member is located between the PCB and the shielding member.

14. The wearable device of claim 3, wherein the second cover is formed of a non-conductive material.

15. The wearable device of claim 1, wherein the protection circuit includes a transient voltage suppressor (TVS) diode or a varistor.

16. The wearable device of claim 1, comprising:
a sensor configured to detect biometric information of a user using the metal cover.

17. The wearable device of claim 1, comprising:
a third cover coupled to the metal cover to close a hollow formed in the metal cover,
wherein the third cover includes a glass plate and a metal layer deposited on the glass plate.

18. The wearable device of claim 1, wherein the metal cover is not directly electrically connected to the conductive member.

19. A wearable device comprising:
a housing including a first cover including a conductive portion;
a printed circuit board (PCB) within the housing;
a protection circuit on the PCB;
a sensor within the housing configured to detect biometric information of a user using the conductive portion of the first cover; and
a conductive member disposed between the PCB and the first cover to overlap the conductive portion,
wherein the protection circuit is electrically connected to a ground of the PCB, and
wherein the conductive member is electrically connected to the protection circuit to form a path for electrostatic discharge by the conductive portion.

20. The wearable device of claim 19, comprising:
a connector disposed on the PCB and electrically connected to the protection circuit,
wherein the housing includes a second cover coupled to the first cover,
wherein the second cover includes a support portion including a first surface facing the first cover and a second surface opposite to the first surface and facing the PCB,
wherein the conductive member includes:
a first portion disposed on the first surface of the support portion,
a second portion extending from the first portion to pass through the support portion, and
a third portion contacting the connector and extending from the second portion to the connector, and
wherein the conductive member is electrically connected to the protection circuit through the connector.
